(19) United States
(12) Patent Application Publication
(10) Pub. No.: US 2026/0190482 A1
(43) Pub. Date: Jul. 2, 2026

(54) DISPLAY DEVICE

(71) Applicant: LG Display Co., Ltd., Seoul (KR)

(72) Inventors: Hyunki Kim, Paju-si (KR); Sohyung Lee, Paju-si (KR); KwangHeum Lee, Paju-si (KR); Chaewoon Lee, Paju-si (KR)

(73) Assignee: LG Display Co., Ltd., Seoul (KR)

(21) Appl. No.: 19/337,445

(22) Filed: Sep. 23, 2025

(30) Foreign Application Priority Data
Dec. 31, 2024 (KR) 10-2024-0202935

(51) Int. Cl. H10D 86/40; G09G 3/3233; G09G 3/3266; H10D 86/60

(52) U.S. Cl. CPC H10D 86/421; G09G 3/3233; G09G 3/3266; H10D 86/451; H10D 86/60; G09G 2300/0408; G09G 2300/0426; G09G 2300/0842; G09G 2310/0291

(57) ABSTRACT

A display device includes a transistor on a substrate. The transistor includes an active layer, first and second gate insulation layers each on the active layer and spaced apart in a first direction, first and second gate electrodes respectively on the first and second gate insulation layers and spaced apart, a drain electrode connected to the active layer, and a source electrode connected to another portion of the active layer. The active layer includes a first channel portion overlapping the first gate electrode, a second channel portion overlapping the second gate electrode, a first conductive portion positioned in the first direction of the second channel portion, a second conductive portion positioned between the first channel portion and the second channel portion, and a third conductive portion positioned in a second direction opposite to the first direction of the first channel portion.

### CROSS-REFERENCE TO RELATED APPLICATION

This application claims priority from Korean Patent Application No. 10-2024-0202935, filed on Dec. 31, 2024, which is hereby incorporated by reference for all purposes as if fully set forth herein.

### BACKGROUND

### Technical Field

Embodiments of the disclosure relate to a display device.

### Discussion of the Related Art

Display devices are applied to various electronic devices, such as TVs, mobile phones, laptops, and tablets. Display devices include organic light emitting displays (OLEDs), which are self-emissive, and liquid crystal displays (LCDs), which require a separate light source.

For image display, a display device may include a display panel where a plurality of data lines and a plurality of gate lines are disposed, a data driving circuit outputting data signals to the plurality of data lines, and a gate driving circuit outputting gate signals to the plurality of gate lines.

Transistors are widely used as switching elements or driving elements in the field of electronic devices. Thin film transistors may be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

### SUMMARY

Accordingly, embodiments of the present disclosure are directed to a display device that substantially obviates one or more of the problems due to limitations and disadvantages of the related art.

An aspect of the present disclosure is to provide a display device having a transistor capable of improving short channel element characteristics and preventing deterioration due to hydrogen inflow.

Another aspect of the present disclosure is provide a display device having a transistor capable of preventing deterioration due to lateral stress.

Another aspect of the present disclosure is to provide a display device having a transistor capable of improving a turn-on current reduction phenomenon.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate, and a transistor disposed on the substrate. The transistor may include an active layer on the substrate, a first gate insulation layer disposed on the active layer, a second gate insulation layer disposed on the active layer, and spaced apart from the first gate insulation layer in a first direction, a first gate electrode disposed on the first gate insulation layer, a second gate electrode disposed on the second gate insulation layer, and spaced apart from the first gate electrode, a drain electrode connected to a portion of the active layer, and a source electrode connected to another portion of the active layer. The active layer may include a first channel portion overlapping at least a portion of the first gate electrode, a second channel portion overlapping at least a portion of the second gate electrode, a first conductive portion positioned in the first direction of the second channel portion, a second conductive portion positioned between the first channel portion and the second channel portion, and a third conductive portion positioned in a second direction opposite to the first direction of the first channel portion.

According to embodiments of the disclosure, there may be provided a display device having a transistor capable of improving short channel element characteristics and preventing deterioration due to hydrogen inflow.

According to embodiments of the disclosure, there may be provided a display device having a transistor capable of preventing deterioration due to lateral stress.

According to embodiments of the disclosure, there may be provided a display device having a transistor capable of improving a turn-on current reduction phenomenon.

According to embodiments of the disclosure, there may be provided a display device having a transistor capable of preventing deterioration of element characteristics. Thus, the efficiency and lifespan of the display device may increase, reducing unnecessary power consumption, and hence allowing for low power consumption.

It is to be understood that both the foregoing general description and the following detailed description are exemplary and explanatory and are intended to provide further explanation of the inventive concepts as claimed.

### DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 illustrates a display device according to embodiments of the disclosure;

FIG. 2 is an equivalent circuit diagram illustrating a subpixel of a display device according to embodiments of the disclosure;

FIG. 3 is a cross-sectional view illustrating a display panel according to embodiments of the disclosure;

FIG. 4 illustrates a gate-in panel circuit of a display device according to embodiments of the disclosure;

FIG. 5 illustrates a transistor including first and second transistors in a display device according to embodiments of the disclosure;

FIG. 6 is a cross-sectional view and a plan view illustrating a transistor including first and second transistors in a display device according to embodiments of the disclosure;

FIG. 7 illustrates a transistor including first to third transistors in a display device according to embodiments of the disclosure;

FIG. 8 is a cross-sectional view and a plan view illustrating a transistor including first to third transistors in a display device according to embodiments of the disclosure;

FIG. 9 is an enlarged cross-sectional view illustrating a transistor in a display device according to embodiments of the disclosure;

FIG. 10 illustrates a transistor including first and second transistors in a display device according to embodiments of the disclosure;

FIG. 11 is a cross-sectional view illustrating a transistor including first and second transistors in a display device according to embodiments of the disclosure;

FIG. 12 illustrates a transistor including first to third transistors in a display device according to embodiments of the disclosure;

FIGS. 13 to 15 are cross-sectional views illustrating a transistor including first to third transistors in a display device according to embodiments of the disclosure;

FIG. 16 illustrates a transistor including first to third transistors in a display device according to embodiments of the disclosure;

FIGS. 17 and 18 are cross-sectional views illustrating a transistor including first to third transistors in a display device according to embodiments of the disclosure;

FIG. 19 illustrates a transistor including first to third transistors in a display device according to embodiments of the disclosure;

FIGS. 20 and 21 are cross-sectional views illustrating a transistor including first to third transistors in a display device according to embodiments of the disclosure;

FIG. 22 illustrates a transistor including first to fifth transistors in a display device according to embodiments of the disclosure;

FIG. 23 is a cross-sectional view illustrating a transistor including first to fifth transistors in a display device according to embodiments of the disclosure; and

FIG. 24 is a plan view illustrating a transistor including first to fifth transistors in a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

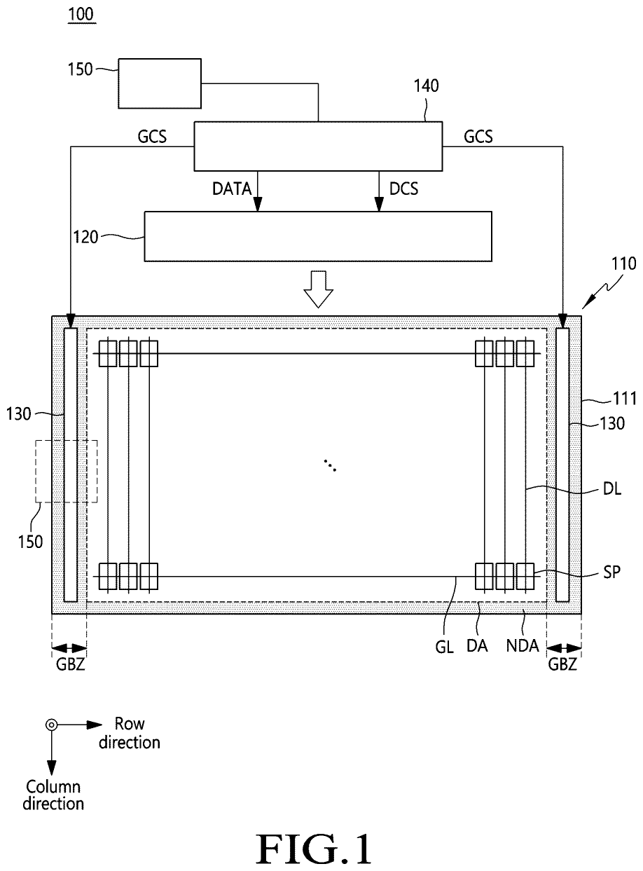

FIG. 1 is a view illustrating a configuration of a display device 100 according to embodiments of the disclosure.

Referring to FIG. 1, a display device 100 according to embodiments of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140 outputting a gate control signal GCS and a data control signal DCS to control the gate driving circuit 130 and the data driving circuit 120 respectively, but embodiments of the disclosure are not limited thereto.

The display panel 110 may include a substrate 111 and a plurality of subpixels SP disposed on the substrate 111.

The substrate 111 may include a display area DA and a non-display area NDA. The display area DA is an area where images may be displayed, and may also be referred to as an active area. A plurality of subpixels SP for image display may be disposed in the display area DA. The non-display area NDA is an area where no image is displayed and may be an area outside the display area DA. The non-display area NDA may be referred to as a bezel. The non-display area NDA may include a pad area.

The display device 100 according to embodiments of the disclosure may be a self-emission display device in which the display panel 110 emits light by itself, but embodiments of the disclosure are not limited thereto.

For example, the display device 100 may be an organic light emitting diode display in which the light emitting element is implemented as an organic light emitting diode (OLED). As another example, the display device 100 may be an inorganic light emitting display device in which the light emitting element is implemented as an inorganic material-based light emitting diode. As another example, the display device 100 may be a quantum dot display device in which the light emitting element is implemented as a quantum dot which is self-emission semiconductor crystal. As another example, the display device 100 may be a micro LED display device or a mini LED display device.

The structure of each of the plurality of subpixels SP may vary according to the type of the display device 100. For example, when the display panel 110 is a self-luminous display device, each subpixel SP may include a light emitting element that emits light, one or more transistors, and one or more capacitors. However, embodiments of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed while extending in the row direction. Each of the plurality of data lines DL may be disposed while extending in a column direction different from the row direction. The row direction and the column direction may be relative directions. For example, the angle between the row direction and the column direction may be 90 degrees or may an angle different from 90 degrees.

The data driving circuit 120 may receive digital image data DATA from the controller 140 and may convert the received image data DATA into analog data signals (or also referred to as data voltages) and output them to the plurality of data lines DL.

The gate driving circuit 130 is a circuit for driving the plurality of gate lines GL, and may output gate signals to the plurality of gate lines GL.

The gate driving circuit 130 may be embedded in the display panel 110 in a gate-in-panel (GIP) type. In this case, the gate driving circuit 130 may be formed on the substrate 111 of the display panel 110 during the manufacturing process of the display panel 110. When the gate driving circuit 130 is of a gate-in-panel type, the gate driving circuit 130 may be referred to as a gate-in-panel circuit (GIPC).

For example, the gate driving circuit 130 may be disposed in the non-active area NDA of the display panel 110. For example, the gate driving circuit 130 may be disposed in the non-display area NDA on one side or the other side of the display area DA. As another example, gate driving circuits 130 may be disposed in the non-display area NDA on two opposite sides of the display area DA.

As another example, the gate driving circuit 130 may be disposed in the display area DA of the display panel 110. For example, the gate driving circuit 130 may be disposed in the left area or the right area within the display area DA. As another example, the gate driving circuit 130 may be disposed over the entire display area DA.

Referring to FIG. 1, the non-display area NDA of the display panel 110 may include a gate bezel area GBZ in which the gate driving circuit 130 and related lines are disposed.

The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material.

For example, the first semiconductor material and the second semiconductor material may be identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be a semiconductor layer.

For example, the active layer may be a single layer. As another example, the active layer may be multiple layers.

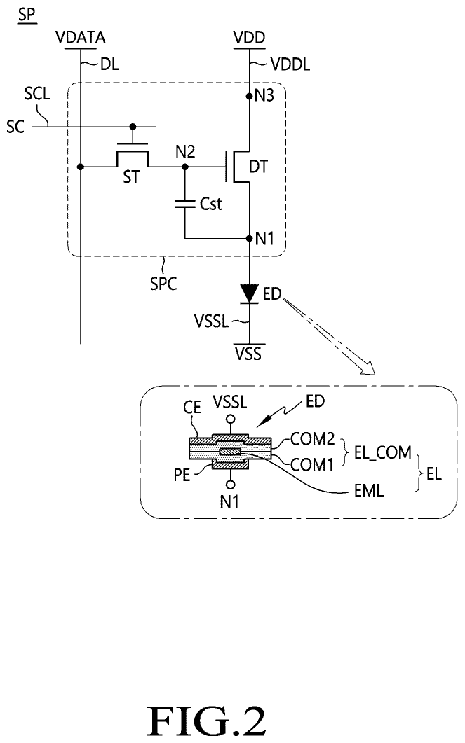

FIG. 2 is an equivalent circuit diagram illustrating a subpixel SP of a display device 100 according to embodiments of the disclosure.

Referring to FIG. 2, when the display device 100 is a self-luminous display device, each of the plurality of subpixels SP disposed on the substrate 111 may include a light emitting element ED and a subpixel circuit SPC for driving the light emitting element ED.

The subpixel circuit SPC may include a plurality of transistors and at least one capacitor for driving the light emitting element ED. The subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a kind of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode.

When the light emitting element ED is an organic light emitting element, the intermediate layer EL may include a light emitting layer EML and a common intermediate layer EL_COM. The common layer EL_COM may include a first common intermediate layer COM1 between the pixel electrode PE and the light emitting layer EML, and a second common intermediate layer COM2 between the light emitting layer EML and the common electrode CE.

The common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node N1 of the driving transistor DT of each subpixel SP. In the disclosure, “base voltage VSS” may also be referred to as a first common voltage, a low-potential power voltage, or a low-potential voltage, and “base voltage line VSSL” may also be referred to as a first common voltage line, a low-potential power voltage line, or a low-potential voltage line.

Each light emitting element ED may include portions where the pixel electrode PE, the intermediate layer EL, and the common electrode CE overlap. A predetermined light emitting area may be formed by each light emitting element ED.

For example, the light emitting element ED may be an organic light emitting diode (OLED), an inorganic light emitting diode (LED), a quantum dot light emitting element, a micro LED, or a mini LED, but embodiments of the disclosure are not limited thereto.

The driving transistor DT may be a driving transistor for supplying a driving current to the light emitting element ED. The driving transistor DT may be connected between a driving voltage line VDDL and the light emitting element ED.

The driving transistor DT may include a first node N1, a second node N2, and a third node N3. The first node N1 may be electrically connected to the light emitting element ED, the second node N2 may receive a data signal VDATA, and the third node N3 may receive a driving voltage VDD, which is another kind of common voltage, from the driving voltage line VDDL. The driving transistor DT may be connected between the first node N1 and the third node N3.

In the driving transistor DT, the second node N2 may be a gate node, the first node N1 may be a source node or a drain node, and the third node N3 may be a drain node or a source node. Hereinafter, for convenience of description, an example is described in which in the driving transistor DT, the second node N2 may be a gate node, the first node N1 may be a source node, and the third node N3 may be a drain node, but embodiments of the disclosure are not limited thereto.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a kind of gate signal applied through the scan line SCL, which is a type of the gate line GL, to control electrical connection between the second node N2 of the driving transistor DT and the data line DL.

The storage capacitor Cst may be electrically connected between the first node N1 and second node N2 of the driving transistor DT.

As illustrated in FIG. 2, the subpixel circuit SPC may have a 2T (Transistor) 1C (Capacitor) structure including two transistors DT and ST and one capacitor Cst. In some cases, the subpixel circuit SPC may further include one or more transistors or may further include one or more capacitors.

Since the circuit elements (e.g., the light emitting element ED implemented as an organic light emitting diode (OLED) including an organic material) in each subpixel SP are vulnerable to external moisture or oxygen, the encapsulation layer may be disposed on the display panel 110. The encapsulation layer may prevent external moisture or oxygen from penetrating into circuit elements (e.g., the light emitting element ED).

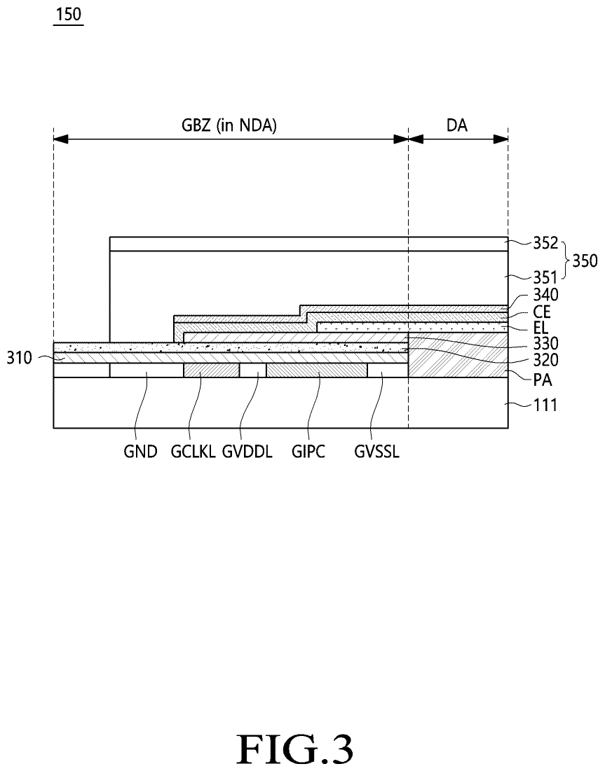

FIG. 3 is a cross-sectional view illustrating a display panel according to embodiments of the disclosure. However, FIG. 3 is a cross-sectional view illustrating an area 150 including a gate bezel area GBZ and a portion of the display area DA of FIG. 1.

Referring to FIG. 3, a display panel according to embodiments of the disclosure may include a gate-in-panel circuit GIPC, at least one first gate voltage line GVDDL disposed outside the gate-in-panel circuit GIPC, at least one second gate voltage line GVSSL disposed inside the gate-in-panel circuit GIPC, and a plurality of gate clock lines GCLKL disposed outside the at least one first gate voltage line GVDDL.

The gate-in-panel circuit GIPC, at least one first gate voltage line GVDDL, at least one second gate voltage line GVSSL, and the plurality of gate clock lines GCLKL may be disposed on the substrate 111, and may be disposed in the gate bezel area GBZ in the non-display area NDA.

Referring to FIG. 3, the display panel according to embodiments of the disclosure may further include a ground line GND disposed outside the plurality of gate clock lines GCLKL.

Referring to FIG. 3, the display panel according to embodiments of the disclosure may include a pixel area PA in the display area DA, and the pixel area PA may further include pixel electrodes PE included in the light emitting elements ED.

Referring to FIG. 3, the display panel according to embodiments of the disclosure may further include a passivation layer 310 disposed on the gate-in-panel circuit GIPC and the plurality of gate clock lines GCLKL, an overcoat layer 320 disposed on the passivation layer 310, and a bank 330 disposed on the overcoat layer 320.

Referring to FIG. 3, the display panel according to embodiments of the disclosure may further include an intermediate layer EL disposed on the bank 330 and the pixel electrodes PE in the pixel area PA and a common electrode CE disposed on the intermediate layer EL.

Referring to FIG. 3, the display panel according to embodiments of the disclosure may further include a capping layer 340 disposed on the common electrode CE.

Referring to FIG. 3, the display panel according to embodiments of the disclosure may further include an encapsulation layer 350 on the capping layer 340. The encapsulation layer 350 may include an adhesive layer 351 on the capping layer 340 and a metal encapsulation layer 352 on the adhesive layer 351.

Referring to FIG. 3, the common electrode CE may be disposed in the display area DA and may extend to the gate bezel area GBZ in the non-display area NDA.

Referring to FIG. 3, in the display panel according to embodiments of the disclosure, the passivation layer 310 may be disposed on the gate-in-panel circuit GIPC. The passivation layer 310 may protect a plurality of transistors that may be disposed in the gate-in-panel circuit GIPC, to insulate between the plurality of transistors, or insulate between the plurality of transistors and the light emitting elements ED.

The passivation layer 310 may be an inorganic layer including an inorganic insulating material. For example, the interlayer insulation layer may include at least one of silicon nitride (SiNₓ), silicon oxide (SiOₓ), or silicon oxynitride (SiOₓN_{y}), but the disclosure is not limited thereto.

For example, when the passivation layer 310 includes silicon nitride (SiNₓ), special gases such as monosilane (SiH₄) and ammonia (NH₃) including a large amount of hydrogen may be used during the process of forming the passivation layer 310. For the reason, the passivation layer 310 includes a large amount of hydrogen, and the hydrogen may be diffused outside the passivation layer 310 in a gaseous or ion state.

The diffused hydrogen may deepen the degree of conduction of the transistor that may be disposed in the gate-in-panel circuit GIPC and accelerate deterioration. Further, as the threshold voltage Vth of the transistor shifts in the negative direction, the image quality of the display panel may deteriorate due to poor luminance of the light emitting element.

Hereinafter, a transistor including a structure capable of improving short channel element characteristics due to the inflow of hydrogen, preventing deterioration, and preventing deterioration of lateral stress that may occur additionally in the transistor among a number of transistors that may be disposed in the gate-in-panel circuit GIPC is described in detail.

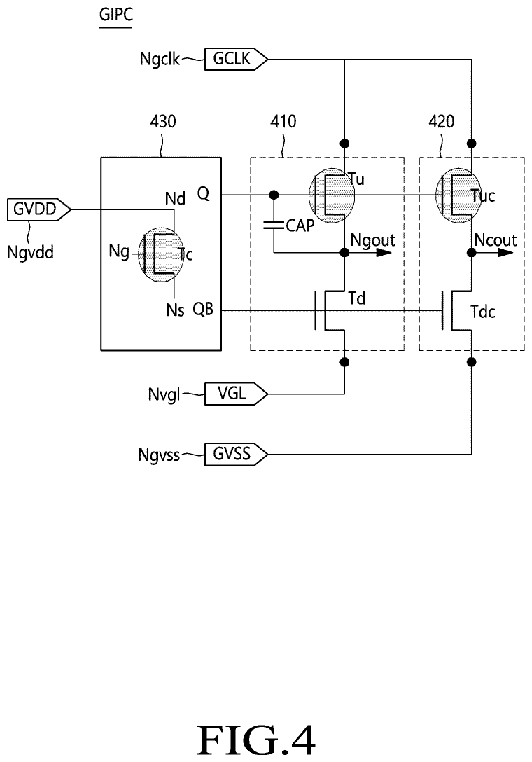

FIG. 4 schematically illustrates a gate-in-panel circuit GIPC of a display device according to embodiments of the disclosure.

Referring to FIG. 4, a gate-in-panel circuit GIPC according to embodiments of the disclosure may include a plurality of gate output buffers 410 for outputting a plurality of gate signals and a control circuit 430 for controlling the plurality of gate output buffers 410. Here, each of the plurality of gate signals may be a scan signal SCAN or a sense signal SENSE.

Each of the plurality of gate output buffers 410 may be configured to receive a gate clock signal GCLK and a low-level gate voltage VGL and output a gate signal to the gate output node Ngout.

The gate output buffer 410 may include a pull-up transistor Tu into which the gate clock signal GCLK is input and a pull-down transistor Td into which the low-level gate voltage VGL is input.

The gate output buffer 410 may output a gate signal to the gate output node Ngout where the pull-up transistor Tu and the pull-down transistor Td are connected.

The pull-up transistor Tu may be connected between the gate clock node Ngclk and the gate output node Ngout, and may switch a connection between the gate clock node Ngclk and the gate output node Ngout.

The pull-down transistor Td may be connected between the low-level gate voltage node Nvgl and the gate output node Ngout, and may switch a connection between the low-level gate voltage node Nvgl and the gate output node Ngout.

In the pull-up transistor Tu, a capacitor CAP may be electrically connected between the Q node, which is a gate node, and the gate output node Ngout. The capacitor CAP may serve to boost the voltage of the Q node according to a voltage variation of the gate output node Ngout.

The control circuit 430 may control the voltage of the Q node electrically connected to the gate node of the pull-up transistor Tu and control the voltage of the QB node electrically connected to the gate node of the pull-down transistor Td. Here, the QB node may receive a DC voltage or an AC signal through the control circuit 430.

The control circuit 430 controls the voltage of each of the Q node and the QB node, and may include a control transistor Tc having a drain node to which a high-potential voltage is applied. The high-potential power voltage GVDD may be input to the control transistor Tc through the high-potential power node Ngvdd.

The control transistor Tc may include a plurality of transistors. For example, the control transistor Tc may include one or more transistors for charging the Q node, one or more transistors for discharging the Q node, one or more transistors for charging the QB node, and one or more transistors for discharging the QB node. For example, one or more transistors of the control transistors Tc include a source node Ns, a gate node Ng, and a drain node Nd.

In order to control the voltage of each of the Q node and the QB node, the control circuit 430 may receive a start signal, a reset signal, or the like, and may further receive a carry signal according to a gate driving method.

Referring to FIG. 4, the gate-in-panel circuit GIPC may further include a carry output buffer 420 including a carry-up transistor Tuc to which the gate clock signal GCLK is input and a carry-down transistor Tdc to which the low potential power supply voltage GVSS is input.

The carry output buffer 420 may output a carry signal to a previous stage circuit and/or a next stage circuit through a carry output node Ncout to which the carry pull-up transistor Tuc and the carry pull-down transistor Tdc are connected.

The carry pull-up transistor Tuc may be connected between the gate clock node Ngclk and the carry output node Ncout. The carry pull-down transistor Tdc may be connected between the carry output node Ncout and the low-potential power supply node Ngvss.

The gate node of the pull-up transistor Tu and the gate node of the carry-up transistor Tuc may be connected to the Q node. The gate node of the pull-down transistor Td and the gate node of the carry-down transistor Tdc may be connected to the QB node.

In the display panel according to embodiments of the disclosure, at least one of the pull-up transistor Tu, the carry pull-up transistor Tuc, and the control transistor Tc may have a structure capable of improving short channel element characteristics due to the inflow of hydrogen, preventing deterioration, and mitigating lateral stress deterioration that may additionally occur in the transistor. However, without limitations thereto, it may also be applied to other types of transistors that may be disposed throughout the inside and outside of the gate-in-panel circuit GIPC.

Hereinafter, with reference to a circuit diagram and a cross-sectional view illustrating a transistor having a structure according to embodiments of the disclosure, embodiments classified according to driving methods are described in detail.

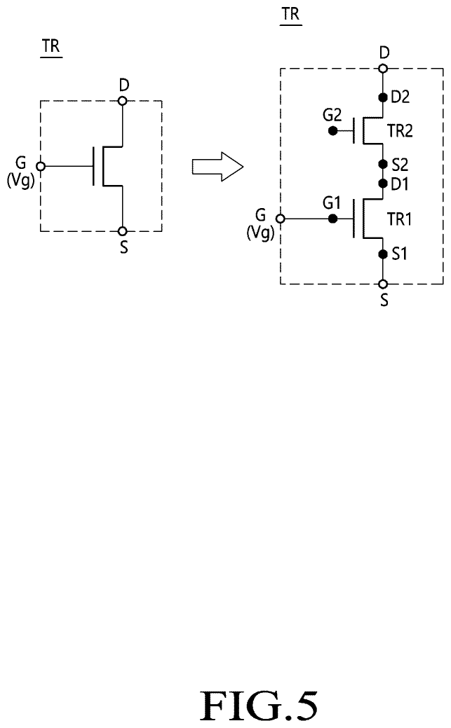

FIG. 5 illustrates a transistor TR including first and second transistors TR1 and TR2 in a display device according to embodiments of the disclosure.

Referring to FIG. 5, the transistor TR included in the display device may include a source node S, a drain node D, and a gate node G. A gate voltage Vg may be applied to the gate node G.

Referring to FIG. 5, the transistor TR included in the display device may include a first transistor TR1 and a second transistor TR2. The first transistor TR1 may include a first source node S1, a first drain node D1, and a first gate node G1. The second transistor TR2 may include a second source node S2, a second drain node D2, and a second gate node G2.

The first transistor TR1 and the second transistor TR2 may be connected in series. The first drain node D1 of the first transistor TR1 may be electrically connected to the second source node S2 of the second transistor.

The first source node S1 of the first transistor TR1 may be the source node S of the transistor TR, and the second drain node D2 of the second transistor TR2 may be the drain node D of the transistor TR.

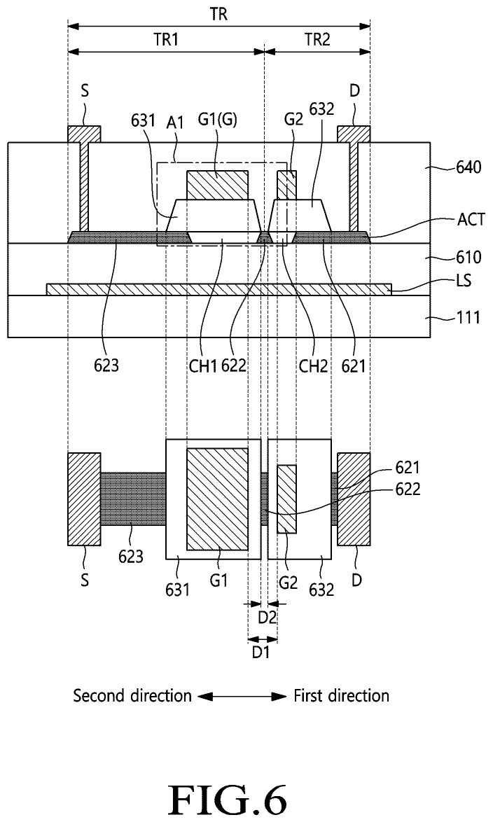

Hereinafter, a cross-sectional structure and a planar structure of the transistor TR of FIG. 5 are described with reference to FIG. 6.

FIG. 6 is a cross-sectional view and a plan view illustrating a transistor TR including first and second transistors TR1 and TR2 in a display device according to embodiments of the disclosure.

Referring to the cross-sectional view illustrated in FIG. 6, a display panel according to embodiments of the disclosure may include a substrate 111 and a transistor TR disposed on the substrate 111. No duplicate description is given of for substantially the same configuration as the configuration of FIG. 3.

The transistor TR may include an active layer ACT on the substrate 111, a first gate insulation layer 631 disposed on the active layer ACT, and a second gate insulation layer 632 disposed on the active layer ACT and spaced apart from the first gate insulation layer 631 in a first direction.

The transistor TR may include a first gate electrode G1 disposed on the first gate insulation layer 631, and a second gate electrode G2 disposed on the second gate insulation layer 632 and spaced apart from the first gate electrode G1. In other words, the second gate electrode G2 may be spaced apart from the first gate electrode G1 in the first direction.

The active layer ACT may include an oxide semiconductor material, but the disclosure is not limited thereto. For example, the active layer ACT may include amorphous silicon, polysilicon, or low-temperature polysilicon (LTPS).

A partial area of the active layer ACT may include a dopant. The dopant may be impurity ions implanted into the active layer ACT through a doping method. A partial area of the active layer ACT including the dopant may function as a source area and/or a drain area, and the remaining area of the active layer ACT without the dopant may function as a channel area.

Referring to FIG. 6, the active layer ACT may include a first channel portion CH1 overlapping at least a portion of the first gate electrode G1, a second channel portion CH2 overlapping at least a portion of the second gate electrode G2, a first conductive portion 621 positioned in the first direction of the second channel portion CH2, a second conductive portion 622 positioned between the first channel portion CH1 and the second channel portion CH2, and a third conductive portion 623 positioned in the second direction opposite to the first direction of the first channel portion CH1.

In other words, the first channel portion CH1 and the second channel portion CH2 may not include a dopant, and the first to third conductive portions 621, 622, and 623 may include a dopant.

Referring to FIG. 6, the display panel according to embodiments of the disclosure may further include an interlayer insulation layer 640 disposed on the first gate electrode G1 and the second gate electrode G2. For example, the interlayer insulation layer 640 may be disposed to cover the active layer ACT, the first gate insulation layer 631, the second gate insulation layer 632, the first gate electrode G1, and the second gate electrode G2.

Referring to FIG. 6, the interlayer insulation layer 640 may be interposed in a space where the first gate electrode G1 and the second gate electrode G2 are spaced apart from each other and a space where the first gate insulation layer 631 and the second gate insulation layer 632 are spaced apart from each other to contact an upper surface of the second conductive portion 622.

The interlayer insulation layer 640 may be an inorganic layer including an inorganic insulating material. For example, the interlayer insulation layer 640 may include at least one of silicon nitride (SiNₓ), silicon oxide (SiOₓ), or silicon oxynitride (SiOₓN_{y}), but the disclosure is not limited thereto.

Referring to FIG. 6, the drain electrode D is disposed on the interlayer insulation layer 640 and is connected to a portion of the active layer ACT through a hole of the interlayer insulation layer 640, and the source electrode S is disposed on the interlayer insulation layer 640 and is connected to a portion of the active layer ACT through a hole of the interlayer insulation layer 640. The drain electrode D may be connected to the first conductive portion 621, and the source electrode S may be connected to the third conductive portion 623.

Referring to FIG. 6, the display panel according to embodiments of the disclosure may further include a buffer layer 610 between the substrate 111 and the active layer ACT, and a metal pattern LS disposed between the substrate 111 and the buffer layer 610 and overlapping the first and second channel portions CH1 and CH2. For example, the metal pattern LS may overlap the entire active layer ACT.

The buffer layer 610 may be disposed to cover the metal pattern LS. The thickness of the buffer layer 610 disposed between the metal pattern LS and the active layer ACT may be larger than or equal to the thickness of the first gate insulation layer 631 and the thickness of the second gate insulation layer 632. For example, the thickness of the buffer layer 610 disposed between the metal pattern LS and the active layer ACT may be three times or more of the thickness of the first gate insulation layer 631 and the thickness of the second gate insulation layer 632.

In the display panel according to embodiments of the disclosure, the metal pattern LS may be at least one of a light blocking layer, a line, and an electrode. Accordingly, the metal pattern LS may have one of a state not connected to the transistor TR, a state where the gate voltage applied to the first gate electrode G1 is applied, a state where the ground voltage is applied, and an electrically floated state.

The plan view illustrated in FIG. 6 may represent an upper surface of the transistor TR including the first transistor TR1 and the second transistor TR2. The source electrode S and the drain electrode D may be disposed at two opposite ends of the transistor TR. The first and second gate insulation layers 631 and 632 and the first and second gate electrodes G1 and G2 may be disposed between the source electrode S and the drain electrode D. A third conductive portion 623 may be disposed between the source electrode S and the first gate insulation layer 631, a second conductive portion 622 may be disposed between the first gate insulation layer 631 and the second gate insulation layer 632, and a first conductive portion 621 may be disposed between the second gate insulation layer 632 and the drain electrode D.

Referring to the plan view illustrated in FIG. 6, a distance D1 at which the second gate electrode G2 is spaced apart from the first gate electrode G1 may be equal to or larger than a distance D2 at which the second gate insulation layer 632 is spaced from the first gate insulation layer 631 and a length D2 of an upper surface of the second conductive portion 622. The separation distance D1 between the first gate electrode G1 and the second gate electrode G2, the separation distance D2 between the first gate insulation layer 631 and the second gate insulation layer 632, and the length D2 of the upper surface of the second conductive portion 622 may be described by the above-described process of forming the structure of the transistor TR.

Although not illustrated, the active layer ACT of the transistor TR may be formed in the display panel according to embodiments of the disclosure, and the gate insulation layer material and the gate electrode material may be sequentially stacked. A first gate electrode G1 and a second gate electrode G2 may be formed by a patterning process on the gate electrode material. A first photo pattern and a second photo pattern may be formed on the upper portions of the first gate electrode G1 and the second gate electrode G2, respectively, by applying a photoresist (PR) material. The first photo pattern and the second photo pattern may be spaced apart from each other, and may have a separation distance shorter than the separation distance between the first gate electrode G1 and the second gate electrode G2. For example, the separation distance between the first photo pattern and the second photo pattern may be 2 μm.

The first gate insulation layer 631 and the second gate insulation layer 632 may be formed by etching the gate insulation layer material using the first photo pattern and the second photo pattern as masks. The gate insulation layer material may be etched through a dry etching process. A portion of the active layer ACT exposed by the patterned first gate insulation layer 631 and the second gate insulation layer 632 may be rendered conductive by a dry etching process. In other words, a dopant may be injected into the first to third conductive portions 621, 622, and 623 of the active layer ACT by a dry etching process.

As a result, since the gate insulation layer material is etched considering the maximum process margin between the first gate electrode G1 and the second gate electrode G2, the width of the upper surface of the second conductive portion 622 may be minimized.

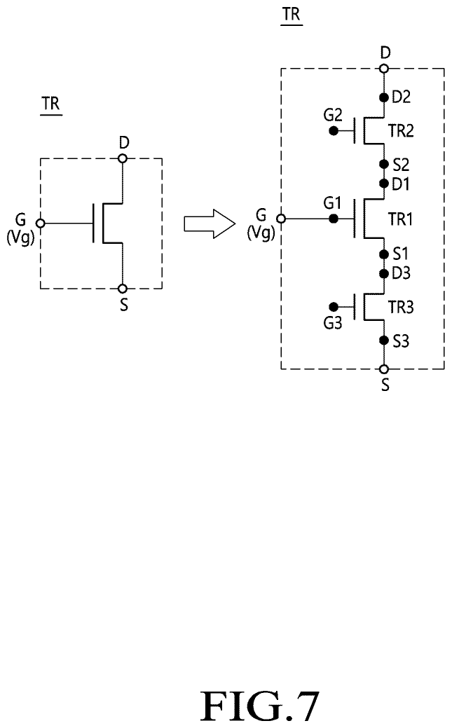

FIG. 7 illustrates a transistor TR including first to third transistors TR1, TR2, and TR3 in a display device according to embodiments of the disclosure. No duplicate description is given of for substantially the same configuration as the configuration of FIG. 5.

Referring to FIG. 7, the transistor TR included in the display device may include first to third transistors TR1, TR2, and TR3. The first transistor TR1 may include a first source node S1, a first drain node D1, and a first gate node G1. The second transistor TR2 may include a second source node S2, a second drain node D2, and a second gate node G2. The third transistor TR3 may include a third source node S3, a third drain node D3, and a third gate node G3.

The first to third transistors TR1, TR2, and TR3 may be connected in series. The first drain node D1 of the first transistor TR1 may be electrically connected to the second source node S2 of the second transistor, and the first source node S1 of the first transistor TR1 may be electrically connected to the third drain node D3 of the third transistor.

The third source node S3 of the third transistor TR3 may be the source node S of the transistor TR, and the second drain node D2 of the second transistor TR2 may be the drain node D of the transistor TR.

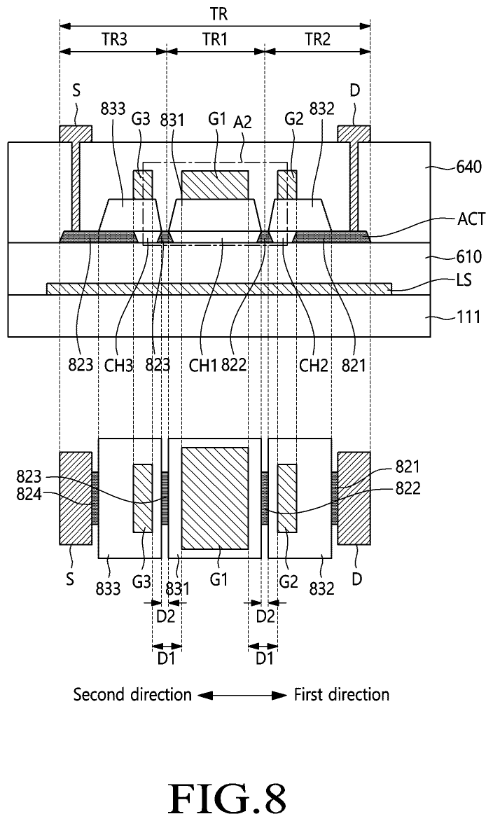

Hereinafter, a cross-sectional structure of the transistor TR of FIG. 7 is described with reference to FIG. 8.

FIG. 8 is a cross-sectional view and a plan view of a display panel according to embodiments of the disclosure.

A display panel according to embodiments of the disclosure may include a substrate 111 and a transistor TR disposed on the substrate 111. No duplicate description is given of for substantially the same configuration as the configuration of FIG. 6.

The transistor TR may further include a third gate insulation layer 833 disposed on the active layer ACT and spaced apart from the first gate insulation layer 831 in the second direction, and a third gate electrode G3 disposed on the third gate insulation layer 833 and spaced apart from the first gate electrode G1.

The thickness of the buffer layer 610 disposed between the metal pattern LS and the active layer ACT may be larger than or equal to the thicknesses of the first to third gate insulation layers 831, 832, and 833. For example, the thickness of the buffer layer 610 disposed between the metal pattern LS and the active layer ACT may be three times or more of the thicknesses of the first to third gate insulation layers 831, 832, and 833.

Referring to FIG. 8, the active layer ACT may include a third channel portion CH3 positioned in the second direction from the third conductive portion 823 and overlapping at least a portion of the third gate electrode G3, and a fourth conductive portion 824 positioned in the second direction from the third channel portion CH3.

The third channel portion CH3 may not include a dopant, and the fourth conductive portion 824 may include a dopant.

At least a portion of the first conductive portion 821 may overlap the second gate electrode G2, the second conductive portion 822 may not overlap the first gate electrode G1 and the second gate electrode G2, the third conductive portion 823 may not overlap the first gate electrode G1 and the third gate electrode G3, and at least a portion of the fourth conductive portion 824 may overlap the third gate electrode G3.

Referring to FIG. 8, an interlayer insulation layer 640 may be disposed on the first gate electrode G1 and the third gate electrode G3. The interlayer insulation layer 640 may be disposed to cover the active layer ACT, the first to third gate insulation layers 831, 832, and 833, and the first to third gate electrodes G1, G2, and G3.

Referring to FIG. 8, the interlayer insulation layer 640 may be interposed in a space where the first gate electrode G1 and the third gate electrode G3 are spaced apart from each other and a space where the first gate insulation layer 831 and the third gate insulation layer 833 are spaced apart from each other to contact an upper surface of the third conductive portion 823.

Referring to FIG. 8, the drain electrode D may be connected to the first conductive portion 821 through a hole of the interlayer insulation layer 640, and the source electrode S may be connected to the fourth conductive portion 824 through another hole of the interlayer insulation layer 640.

Referring to FIG. 8, in the display device according to embodiments of the disclosure, the metal pattern LS may have one of a state not connected to the transistor TR, a state where the gate voltage applied to the first gate electrode G1 is applied, a state where the ground voltage is applied, and a state where the metal pattern LS is electrically floated.

The plan view illustrated in FIG. 8 may represent an upper surface of the transistor TR including the first to third transistors TR1, TR2, and TR3. The first to third gate insulation layers 831, 832, and 833 and the first to third gate electrodes G1, G2, and G3 may be disposed between the source electrode S and the drain electrode D. A fourth conductive portion 824 may be disposed between the source electrode S and the third gate insulation layer 833, a third conductive portion 823 may be disposed between the third gate insulation layer 833 and the first gate insulation layer 831, a second conductive portion 822 may be disposed between the first gate insulation layer 831 and the second gate insulation layer 832, and a first conductive portion 821 may be disposed between the second gate insulation layer 832 and the drain electrode D.

In the display device according to embodiments of the disclosure, since the gate insulation layer material is etched considering the maximum value of the process margin between the first gate electrode G1 and the third gate electrode G3, the length of the upper surface of the third conductive portion 823 may be minimized.

Accordingly, the distance D1 at which the third gate electrode G3 is spaced apart from the first gate electrode G1 may be larger than or equal to the distance D2 at which the third gate insulation layer 833 is spaced from the first gate insulation layer 831 and the width D2 of the upper surface of the third conductive portion 823.

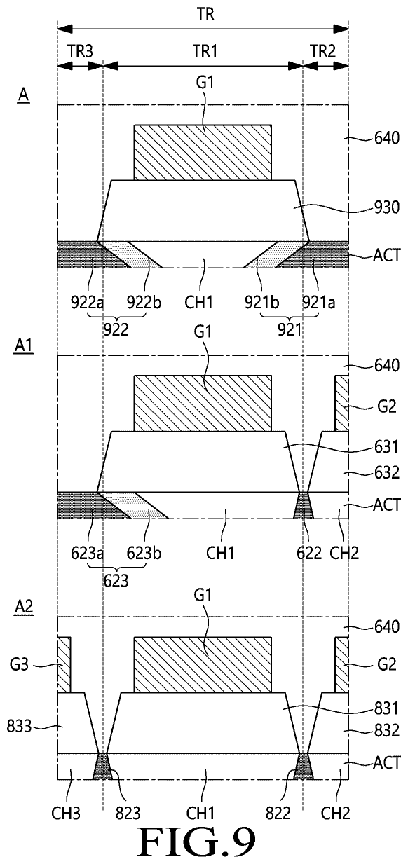

FIG. 9 is an enlarged cross-sectional view illustrating a transistor TR in a display device according to embodiments of the disclosure.

The area A is an enlarged cross-sectional view illustrating a comparative example of a transistor TR including only the first gate electrode G1, the first gate insulation layer 930, and the active layer ACT, unlike a display device according to embodiments of the disclosure.

Referring to FIG. 9, the active layer ACT of the area A may include a first channel portion CH1, a first connection portion 921, and a second connection portion 922, and the first connection portion 921 and the second connection portion 922 may include a dopant.

At least a portion of the first connection portion 921 may overlap the first gate electrode G1, and at least a portion of the second connection portion 922 may overlap the first gate electrode G1. The first main conductive portion 921a of the first connection portion 921 may be an area that does not overlap the first gate electrode G1, and the first sub conductive portion 921b of the first connection portion 921 may include an area that overlaps the first gate electrode G1. Likewise, the second main conductive portion 922a of the second connection portion 922 may be an area that does not overlap the first gate electrode G1, and the second sub conductive portion 922b of the second connection portion 922 may include an area that overlaps the first gate electrode G1.

The first main conductive portion 921a and the second main conductive portion 922a may be areas into which a dopant is injected by a process of dry-etching the first gate insulation layer 930. The first sub conductive portion 921b and the second sub conductive portion 922b may be areas where dopants are diffused from the first main conductive portion 921a and the second main conductive portion 922a and extend to the first channel portion CH1.

As the first sub conductive portion 921b and the second sub conductive portion 922b are formed, the length of the first channel portion CH1, i.e., the channel length of the transistor TR may be shorter than a predetermined value (hereinafter, the length by which the channel length of the transistor TR has been shortened from the designed value is referred to as “2ΔL”). For the reason, it may be difficult to control the driving of the transistor TR or element characteristics may deteriorate.

Further, in the display panel according to embodiments of the disclosure, the interlayer insulation layer 640 may include hydrogen. For example, when the interlayer insulation layer 640 includes silicon nitride (SiNₓ), special gases such as monosilane (SiH₄) and ammonia (NH₃) including a large amount of hydrogen may be used during the process of forming the interlayer insulation layer 640. For the reason, the interlayer insulation layer 640 includes a large amount of hydrogen therein, and hydrogen may be diffused to the outside of the interlayer insulation layer 640 in a gaseous or ion state.

Since the diffused hydrogen increases the degree of conduction of the active layer ACT, 2ΔL may be increased in the transistor TR. In other words, the length of the first channel portion CH1 may further shorten, and the deterioration of the transistor TR may be accelerated. Further, as the threshold voltage Vth of the transistor TR shifts in the negative direction, a luminance defect of the light emitting element may occur, resulting in a decrease in the image quality of the display panel.

The area A1 is an enlarged cross-sectional view illustrating the first and second transistors TR1 and TR2 of FIG. 6 according to embodiments of the disclosure.

In the display panel according to embodiments of the disclosure, the interlayer insulation layer 640 may include hydrogen, and the first conductive portion 621, the second conductive portion 622, and the third conductive portion 623 may include hydrogen diffused from the interlayer insulation layer 640 and introduced.

Referring to FIG. 9, the second conductive portion 622 of the area A1 may not overlap the first gate electrode G1 and the second gate electrode G2. At least a portion of the third conductive portion 623 may overlap the first gate electrode G1.

The third main conductive portion 623a of the third conductive portion 623 is an area that does not overlap the first gate electrode G1, and the third sub conductive portion 623b of the third conductive portion 623 may include an area that overlaps the first gate electrode G1.

The length of the first channel portion CH1 may be decreased due to the third sub conductive portion 623b formed by diffusion of the dopant from the third main conductive portion 623a. However, since the second conductive portion 622 that does not overlap the first gate electrode G1 does not reduce the length of the first channel portion CH1, deterioration of the transistor TR may be less likely in the area A1 than the area A.

The area A2 is an enlarged cross-sectional view illustrating the first to third transistors TR1, TR2, and TR3 of FIG. 8 according to embodiments of the disclosure.

In the display panel according to embodiments of the disclosure, the interlayer insulation layer 640 may include hydrogen, and the first conductive portion 821, the second conductive portion 822, and the third conductive portion 823 may include hydrogen diffused from the interlayer insulation layer 640 and introduced.

Referring to FIG. 9, the second conductive portion 822 of the area A2 may not overlap the first gate electrode G1 and the second gate electrode G2. The third conductive portion 823 may also not overlap the first gate electrode G1 and the third gate electrode G3.

Since the second conductive portion 822 and the third conductive portion 823 do not reduce the length of the first channel portion CH1, deterioration of the transistor TR may be least likely in the area A2.

As a result, in the display panel according to embodiments of the disclosure, deterioration of the transistor TR may be prevented and reliability may be enhanced by securing a conductive area, i.e., a channel area, that does not overlap the first gate electrode G1 of the transistor TR.

On the other hand, although the length of the first channel portion CH1 may not be decreased because the second conductive portion 822 and the third conductive portion 823 do not overlap the first gate electrode G1, the lateral stress of the transistor TR may increase.

For example, when driving the transistor TR in area A, the carrier may move through the first channel portion CH1 and then sequentially pass through the first sub conductive portion and the first main conductive portion. When the transistor TR in the area A2 is driven, the carrier may directly move to the second conductive portion 822 after passing through the first channel portion CH1. Accordingly, the lateral stress may increase while the carrier concentration increases rapidly, and thus the transistor TR may be deteriorated.

In order to improve the lateral stress of the transistor TR, the resistance of the first channel portion CH1 may be increased. For example, since the length of the first channel portion CH1 in the area A2 is not decreased by the second conductive portion 822 and the third conductive portion 823, it may have a resistance value larger than that of the first channel portion CH1 in the area A and the area A1. Accordingly, the lateral stress generated in the transistor TR may be partially mitigated.

In order to mitigate the lateral stress of the transistor TR, the first to third transistors TR1, TR2, and TR3 may be connected in series to form the transistor TR. The resistance of the first channel portion CH1 may be increased by disposing the second transistor TR2 and the third transistor TR3 that may function as a kind of resistor at two opposite ends of the first transistor TR1.

In the display device according to embodiments of the disclosure, the transistor TR may correspond to at least one of the pull-up transistor Tu, the carry-up transistor Tuc, Tdc, and the control transistor Tc of FIG. 4.

The above-described three types of transistors TR may be transistors TR having a high possibility of deterioration due to lateral stress in the gate-in-panel circuit. For example, when a high-potential voltage is applied to the drain node, such as a control transistor TR, the electric field is concentrated in the active layer ACT on the side of the drain electrode D, accelerating the carrier, and causing impact ionization. For the reason, the possibility of defects in the active layer ACT is increased, and the transistor TR may be deteriorated.

Accordingly, deterioration due to lateral stress of the transistor TR may be prevented by making a change to the driving of each of the first to third transistors TR1, TR2, and TR3, such as applying a different voltage to at least one of the first to third gate electrodes G1, G2, and G3 and the metal pattern LS, from those of the rest.

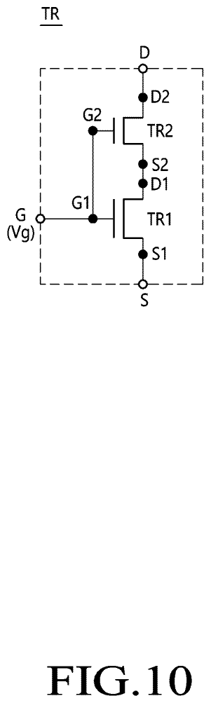

Hereinafter, referring to FIGS. 10 to 24, a method of driving the first to third transistors TR1, TR2, and TR3 that may mitigate deterioration due to lateral stress while preventing deterioration of the element characteristics by reducing 2ΔL is described in detail.

FIG. 10 illustrates a transistor TR including first and second transistors TR1 and TR2 in a display device according to embodiments of the disclosure. No duplicate description is given of for substantially the same configuration as the configuration of FIG. 5.

Referring to FIG. 10, a gate voltage Vg may be applied to the first gate node G1 and the second gate node G2. The first gate node G1 and the second gate node G2 may be electrically connected to each other.

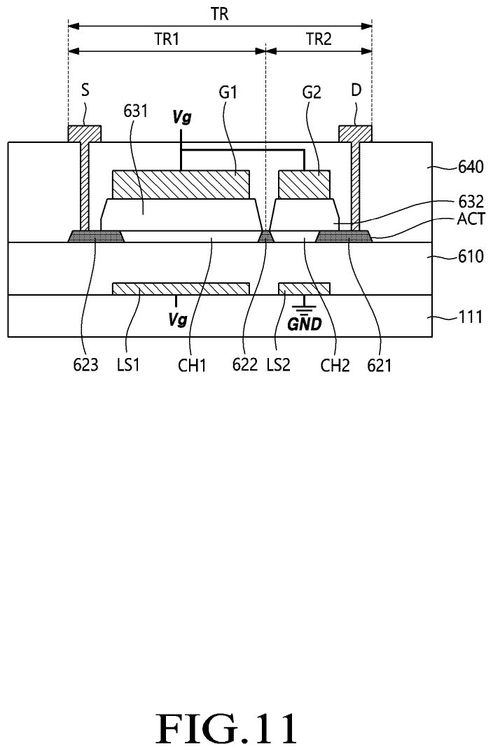

FIG. 11 is a cross-sectional view illustrating a transistor TR including first and second transistors TR1 and TR2 in a display device according to embodiments of the disclosure. FIG. 11 is a cross-sectional view illustrating a transistor TR corresponding to the circuit diagram illustrated in FIG. 10, and no duplicate description may be given of for substantially the same configuration as the configuration of FIG. 6.

The display panel according to embodiments of the disclosure may further include a first metal pattern LS1 disposed between the substrate 111 and the buffer layer 610, overlapping the first channel portion CH1, and a second metal pattern LS2 disposed between the substrate 111 and the buffer layer 610, spaced apart from the first metal pattern LS1, and overlapping the second channel portion CH2.

Referring to FIG. 11, the same gate voltage Vg may be applied to the first gate electrode G1 and the second gate electrode G2, the gate voltage Vg applied to the first gate electrode G1 may be applied to the first metal pattern LS1, and the ground voltage GND may be applied to the second metal pattern LS2.

Accordingly, the first transistor TR1 may have a double gate structure, and the second transistor TR2 may have a top gate structure.

The second transistor TR2 may be positioned in a drain portion receiving the carrier with respect to the first transistor TR1. Therefore, it may be a major factor of lateral stress generated in the transistor TR. For example, when the second transistor TR2 has a double gate structure, the second channel portion CH2 of the second transistor TR2 may have an electric field, i.e., a channel, formed at both the top and the bottom, thereby increasing the number of channels. Therefore, the number of carriers supplied to the drain portion may also increase, and thus lateral stress may increase.

In the example of FIG. 11, since the second transistor TR2 is driven in a top gate structure as the lower channel is suppressed from being formed, deterioration due to lateral stress may be mitigated.

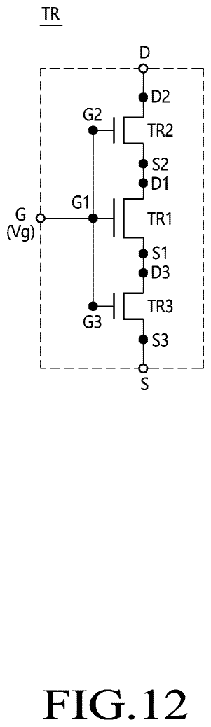

FIG. 12 illustrates a transistor TR including first to third transistors TR1, TR2, and TR3 in a display device according to embodiments of the disclosure. No duplicate description is given of for substantially the same configuration as the configuration of FIG. 7.

Referring to FIG. 12, a gate voltage Vg may be applied to the first to third gate nodes G1, G2, and G3. The first to third gate nodes G1, G2, and G3 may be electrically connected to each other.

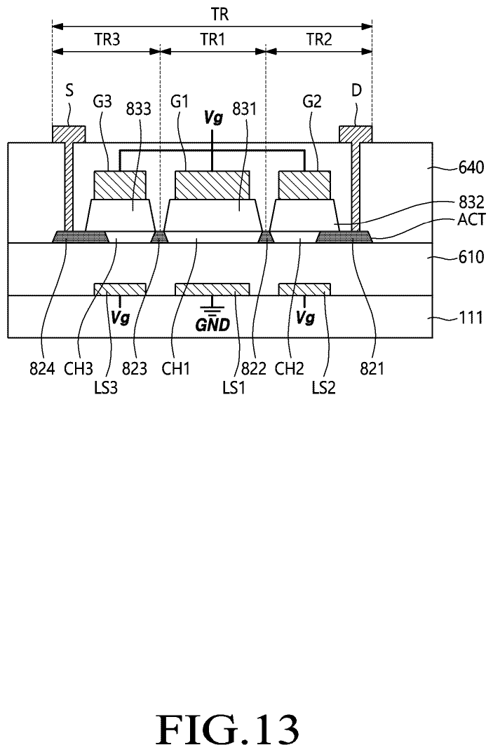

FIGS. 13 to 15 are cross-sectional views illustrating a transistor TR including first to third transistors TR1, TR2, and TR3 in a display device according to embodiments of the disclosure. FIGS. 13 to 15 are cross-sectional views illustrating a transistor TR corresponding to the circuit diagram illustrated in FIG. 12, and no duplicate description may be given of for substantially the same configuration as the configuration of FIG. 8.

Referring to FIG. 13, the display panel according to embodiments of the disclosure may further include a third metal pattern LS3 disposed between the substrate 111 and the buffer layer 610, spaced apart from the first metal pattern LS1, and overlapping the third channel portion.

In the display panel according to embodiments of the disclosure, each of the first metal pattern LS1, the second metal pattern LS2, and the third metal pattern LS3 may have one state among a state not connected to the transistor TR, a state electrically connected to the source electrode S, a state where the gate voltage Vg applied to the first gate electrode G1 is applied, a state where the ground voltage GND is applied, and an electrically floated state.

In the example of FIG. 13, the same gate voltage Vg may be applied to the first to third gate electrodes G1, G2, and G3, the ground voltage GND may be applied to the first metal pattern LS1, and the gate voltage Vg applied to the first gate electrode G1 may be applied to the second metal pattern LS2 and the third metal pattern LS3.

Accordingly, the first transistor TR1 may have a top gate structure, and the second transistor TR2 and the third transistor TR3 may have a double gate structure.

Since the second transistor TR2 has a double gate structure, the second channel portion CH2 of the second transistor TR2 has channels formed at an upper portion and a lower portion thereof, thereby increasing the number of channels and the number of carriers received by the drain portion.

Therefore, in the example of FIG. 13, the second and third conductive portions 822 and 823 are formed to reduce 2ΔL of the first transistor TR1 to prevent deterioration of the element characteristics, but deterioration due to lateral stress may increase.

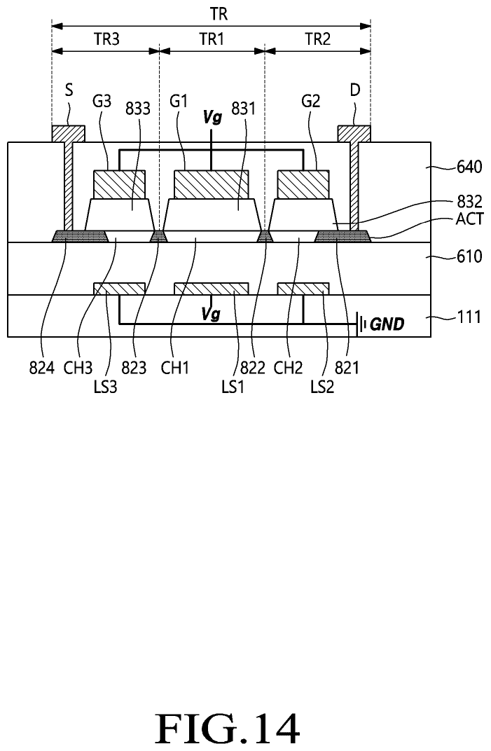

Referring to FIG. 14, the same gate voltage Vg may be applied to the first to third gate electrodes G1, G2, and G3, the gate voltage Vg applied to the first gate electrode G1 may be applied to the first metal pattern LS1, and the ground voltage GND may be applied to the second metal pattern LS2 and the third metal pattern LS3.

Accordingly, in the example of FIG. 14, the first transistor TR1 may have a double gate structure, and the second transistor TR2 and the third transistor TR3 may have a top gate structure.

Since the second transistor TR2 is driven in a top gate structure as the formation of a lower channel is suppressed, the number of carriers received by the drain portion is decreased compared to the example of FIG. 13, thereby mitigating deterioration due to lateral stress.

However, since only the first transistor TR1 is driven in a double gate structure, the turn-on current Ion of the transistor TR may be lowered due to shortage of the total number of channels formed compared to the example of FIG. 13.

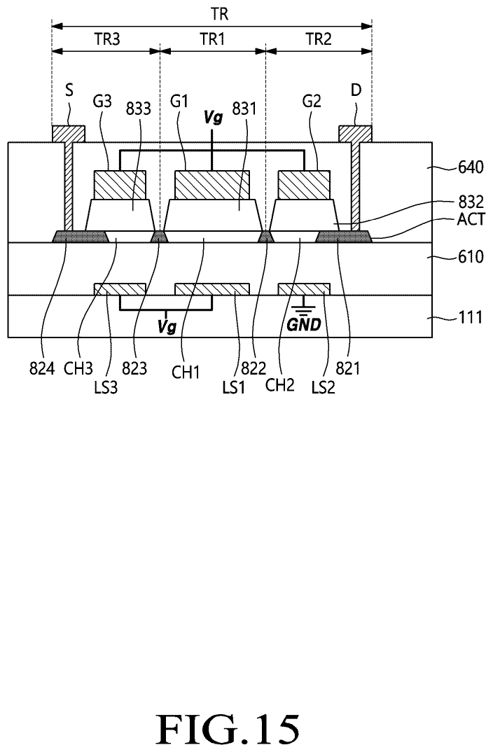

Referring to FIG. 15, the same gate voltage Vg may be applied to the first to third gate electrodes G1, G2, and G3, the gate voltage Vg applied to the first gate electrode G1 may be applied to the first metal pattern LS1 and the third metal pattern LS3, and the ground voltage GND may be applied to the second metal pattern LS2.

Accordingly, in the example of FIG. 15, the first transistor TR1 and the third transistor TR3 may have a double gate structure, and the second transistor TR2 may have a top gate structure.

Since the second transistor TR2 is driven in a top gate structure as the formation of a lower channel is suppressed, the number of carriers received by the drain portion is decreased compared to the example of FIG. 13, thereby mitigating deterioration due to lateral stress.

Since the first transistor TR1 and the third transistor TR3 are driven in a double gate structure, the total number of channels formed is increased compared to the example of FIG. 14, thereby mitigating the decrease in the turn-on current Ion of the transistor TR.

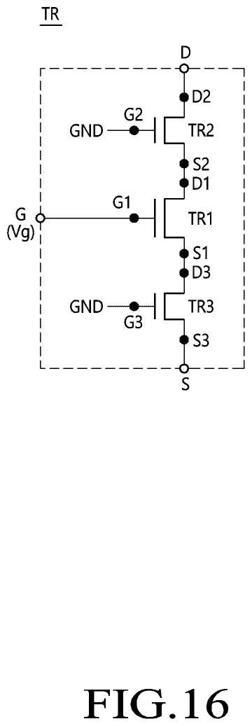

FIG. 16 illustrates a transistor TR including first to third transistors TR1, TR2, and TR3 in a display device according to embodiments of the disclosure. No duplicate description is given of for substantially the same configuration as the configuration of FIG. 7.

Referring to FIG. 16, a gate voltage Vg may be applied to the first gate node G1, and a ground voltage GND may be applied to the second gate node G2 and the third gate node G3.

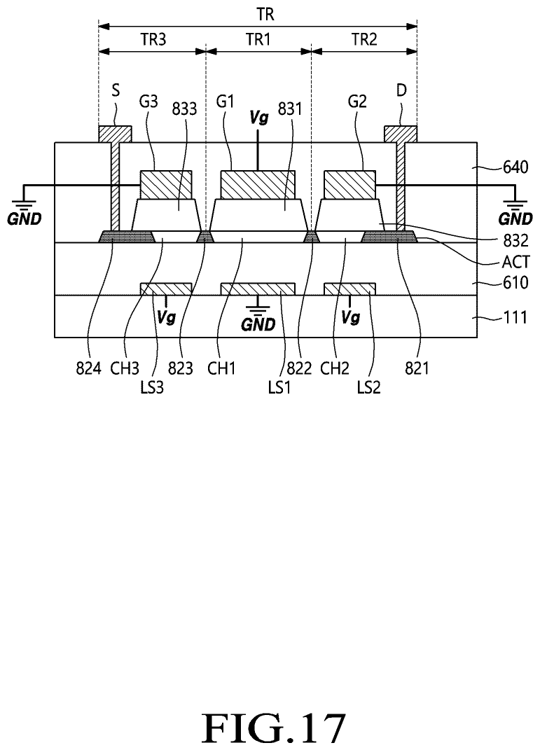

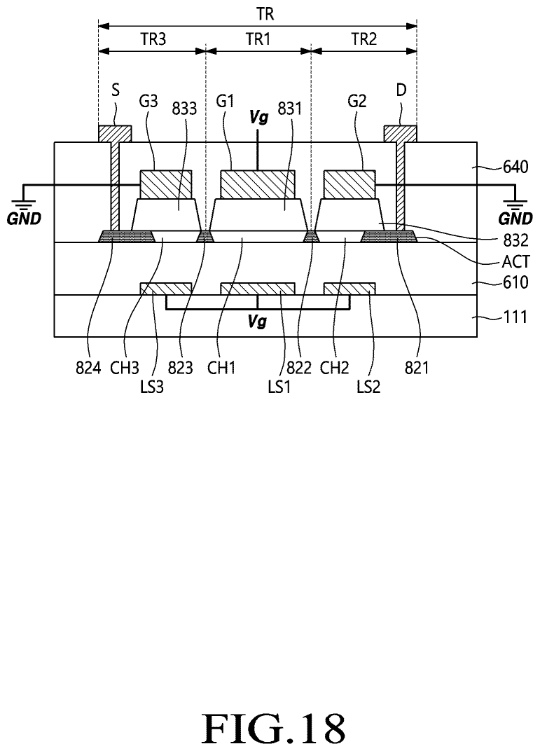

FIGS. 17 and 18 are cross-sectional views illustrating a transistor TR including first to third transistors TR1, TR2, and TR3 in a display device according to embodiments of the disclosure. FIGS. 17 and 18 are cross-sectional views illustrating a transistor TR corresponding to the circuit diagram illustrated in FIG. 16, and no duplicate description may be given of for substantially the same configuration as the configuration of FIG. 8.

Referring to FIG. 17, a gate voltage Vg may be applied to the first gate electrode G1, a ground voltage GND may be applied to the second gate electrode G2 and the third gate electrode G3, a ground voltage GND may be applied to the first metal pattern LS1, and a gate voltage Vg applied to the first gate electrode G1 may be applied to the second and third metal patterns LS3.

Accordingly, in the example of FIG. 17, the first transistor TR1 may have a top gate structure, and the second transistor TR2 and the third transistor TR3 may have a bottom gate structure.

The first transistor TR1 driven in the top gate structure may include a first gate insulation layer 831, and the second transistor TR2 and the third transistor TR3 driven in the bottom gate structure may include a buffer layer 610. Since the thickness of the buffer layer 610 in the display device according to embodiments of the disclosure is equal to or larger than the thicknesses of the first to third gate insulation layers 831, 832, and 833, the second transistor TR2 and the third transistor TR3 have a weaker channel than that of the first transistor TR1 so that less current may flow.

Accordingly, the number of carriers received by the second transistor TR2, i.e., the drain portion of the second transistor TR, may be decreased, thereby mitigating deterioration due to lateral stress.

However, since only the first transistor TR1 is driven in a top gate structure, the turn-on current Ion of the transistor TR may be lowered.

Referring to FIG. 18, a gate voltage Vg may be applied to the first gate electrode G1, a ground voltage GND may be applied to the second gate electrode G2 and the third gate electrode G3, and a gate voltage Vg applied to the first gate electrode G1 may be applied to the first to third metal patterns LS1, LS2, and LS3.

Accordingly, in the example of FIG. 18, the first transistor TR1 may have a double gate structure, and the second transistor TR2 and the third transistor TR3 may have a bottom gate structure.

The number of carriers received by the second transistor TR2, i.e., the drain portion of the second transistor TR may decrease, thereby mitigating deterioration due to lateral stress. Since the first transistor TR1 is driven in a double gate structure, the total number of channels formed is increased compared to the example of FIG. 17, thereby mitigating the decrease in the turn-on current Ion of the transistor TR.

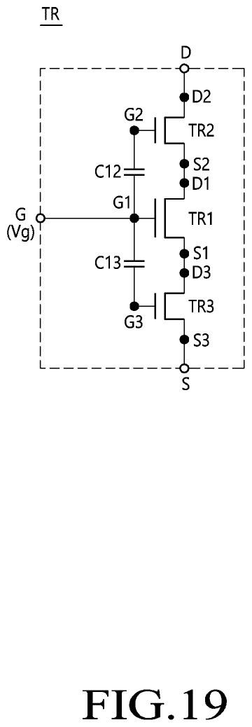

FIG. 19 illustrates a transistor TR including first to third transistors TR1, TR2, and TR3 in a display device according to embodiments of the disclosure. No duplicate description is given of for substantially the same configuration as the configuration of FIG. 7.

Referring to FIG. 19, a gate voltage Vg may be applied to the first gate node G1, and the second gate node G2 and the third gate node G3 may be electrically floated.

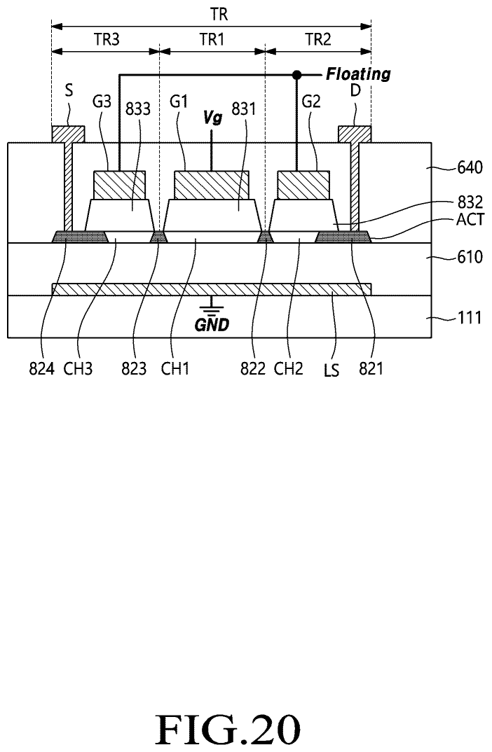

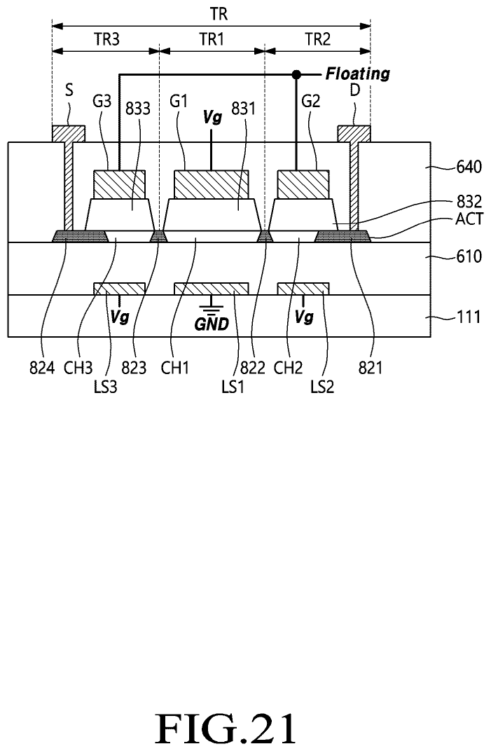

FIGS. 20 and 21 are cross-sectional views illustrating a transistor TR including first to third transistors TR1, TR2, and TR3 in a display device according to embodiments of the disclosure. FIGS. 20 and 21 are cross-sectional views illustrating a transistor TR corresponding to the circuit diagram illustrated in FIG. 19, and no duplicate description may be given of for substantially the same configuration as the configuration of FIG. 8.

Referring to FIG. 20, the gate voltage Vg may be applied to the first gate electrode G1, the second gate electrode G2 and the third gate electrode G3 may be electrically floated, and the ground voltage GND may be applied to the metal pattern LS.

Accordingly, in the example of FIG. 20, the first to third transistors TR1, TR2, and TR3 may have a top gate structure.

Since the second gate electrode G2 and the third gate electrode G3 are in an electrically floated state, a voltage that is very weak compared to the gate voltage Vg applied to the first gate electrode G1 may be applied to the second gate electrode G2 and the third gate electrode G3 by a fringe effect.

Therefore, the number of carriers received by the second transistor TR2, i.e., the drain portion of the transistor TR, may be decreased, thereby mitigating deterioration due to lateral stress.

However, as a very weak voltage is applied to the second gate electrode G2 and the third gate electrode G3, the total gate voltage Vg, i.e., the gate voltage Vg of the entire transistor TR, may decrease, and thus the turn-on current Ion of the transistor TR may decrease.

Referring to FIG. 21, the gate voltage Vg may be applied to the first gate electrode G1, the second gate electrode G2 and the third gate electrode G3 may be electrically floated, the ground voltage GND may be applied to the first metal pattern LS1, and the gate voltage Vg applied to the first gate electrode G1 may be applied to the second metal pattern LS2 and the third metal pattern LS3.

Accordingly, in the example of FIG. 21, the first transistor TR1 may have a top gate structure, and the second transistor TR2 and the third transistor TR3 may have a double gate structure.

Since the second transistor TR2 has a double gate structure, the second channel portion CH2 of the second transistor TR2 has channels formed at an upper portion and a lower portion thereof, thereby increasing the number of channels and causing deterioration due to lateral stress.

Since a very weak voltage is applied to the second gate electrode G2 and the third gate electrode G3, the gate voltage Vg of the entire transistor TR may reduce as compared with deterioration due to lateral stress, increasing the risk of a decrease in turn-on current Ion of the transistor TR. Therefore, when the second gate electrode G2 and the third gate electrode G3 are electrically floated, an amount of current may be secured by driving the second transistor TR2 and the third transistor TR3 in the double gate structure.

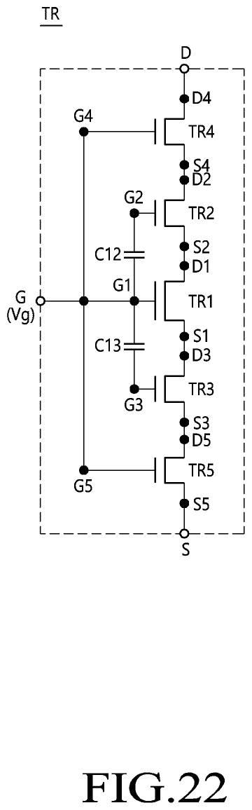

FIG. 22 illustrates a transistor TR including first to fifth transistors TR1, TR2, TR3, TR4, and TR5 in a display device according to embodiments of the disclosure. No duplicate description is given of for substantially the same configuration as the configuration of FIG. 19.

Referring to FIG. 22, the transistor TR included in the display device may further include a fourth transistor TR4 and a fifth transistor TR5. The fourth transistor TR4 may include a fourth source node S4, a fourth drain node D4, and a fourth gate node G4. The fifth transistor TR5 may include a fifth source node S5, a fifth drain node D5, and a fifth gate node G5.

The first to fifth transistors TR1, TR2, TR3, TR4, and TR5 may be connected in series. The second drain node D2 of the second transistor TR2 may be electrically connected to the fourth source node S4 of the fourth transistor TR4, and the third source node S3 of the third transistor TR3 may be electrically connected to the fifth drain node D5 of the fifth transistor TR5.

The fifth source node S5 of the fifth transistor TR5 may be the source node S of the transistor TR, and the fourth drain node D4 of the fourth transistor TR4 may be the drain node D of the transistor TR.

Referring to FIG. 22, the gate voltage Vg may be applied to the first gate node G1, the fourth gate node G4, and the fifth gate node G5, and the second gate node G2 and the third gate node G3 may be electrically floated. The first gate node G1, the fourth gate node G4, and the fifth gate node G5 may be electrically connected to each other.

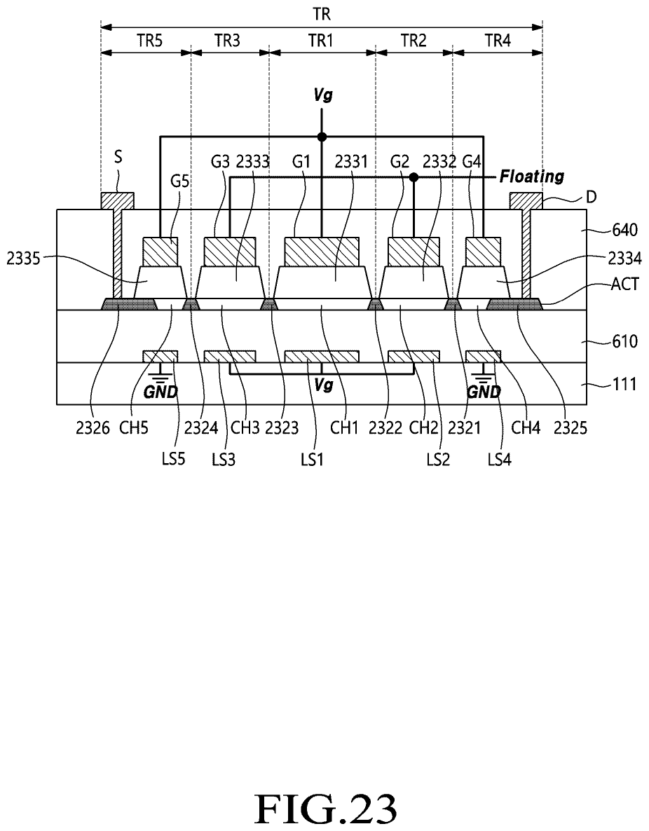

FIG. 23 is a cross-sectional view illustrating a transistor TR including first to fifth transistors TR1, TR2, TR3, TR4, and TR5 in a display device according to embodiments of the disclosure. FIG. 23 is a cross-sectional view illustrating a transistor TR corresponding to the circuit diagram illustrated in FIG. 22, and no duplicate description may be given of for substantially the same configuration as the configuration of FIG. 8.

The transistor TR may further include a fourth gate insulation layer 2334 spaced apart from the second gate insulation layer 2332 in the first direction, a fifth gate insulation layer 2335 spaced apart from the third gate insulation layer 2333 in the second direction, a fourth gate electrode G4 disposed on the fourth gate insulation layer 2334 and spaced apart from the second gate electrode G2, and a fifth gate electrode G5 disposed on the fifth gate insulation layer 2335 and spaced apart from the third gate electrode G3.

Referring to FIG. 23, the active layer ACT may include a fourth channel portion CH4 overlapping at least a portion of the fourth gate electrode G4, a fifth channel portion CH5 overlapping at least a portion of the fifth gate electrode G5, a fifth conductive portion 2325 positioned in the first direction of the fourth channel portion CH4, and a sixth conductive portion 2326 positioned in the second direction of the fifth channel portion CH5. The first conductive portion 2321 may not overlap the second gate electrode G2 and the fourth gate electrode G4, and the fourth conductive portion 2324 may not overlap the third gate electrode G3 and the fifth gate electrode G5. For example, the active layer ACT may further include the second conductive portion 2322 and the third conductive portion 2323.

The drain electrode D may be connected to the fifth conductive portion 2325 through a hole of the interlayer insulation layer 640, and the source electrode S may be connected to the sixth conductive portion 2326 through another hole of the interlayer insulation layer 640.

The display panel according to embodiments of the disclosure may further include a fourth metal pattern LS4 disposed between the substrate 111 and the buffer layer 610 and overlapping the fourth channel portion CH4, and a fifth metal pattern LS5 disposed between the substrate 111 and the buffer layer 610 and overlapping the fifth channel portion CH5.

Referring to FIG. 23, the same gate voltage Vg may be applied to the first gate electrode G1, the fourth gate electrode G4, and the fifth gate electrode G5, and the second gate electrode G2 and the third gate electrode G3 may be electrically floated. The gate voltage Vg applied to the first gate electrode G1 may be applied to the first to third metal patterns LS1, LS2, and LS3, and the ground voltage GND may be applied to the fourth metal patter LS4 and the fifth metal pattern LS5.

Accordingly, in the example of FIG. 23, the first to third transistors TR1, TR2, and TR3 may have a double gate structure, and the fourth transistor TR4 and the fifth transistor TR5 may have a top gate structure.

Since the fourth transistor TR4 and the fifth transistor TR5 are driven in a top gate structure as the formation of a lower channel is suppressed, the number of carriers received by the drain portion of the first transistor TR1 may be decreased compared to the example of FIG. 13, thereby mitigating deterioration due to lateral stress.

When only the first transistor TR1 is driven in a double gate structure, the number of channels formed in the entire transistor TR may be insufficient, and thus the turn-on current Ion of the transistor TR may be lowered. As the second transistor TR2 and the third transistor TR3 are driven in the double gate structure, an amount of current may be secured, mitigating a decrease in the turn-on current Ion of the transistor TR.

Although the second transistor TR2 and the third transistor TR3 have a double gate structure, since a very weak voltage is applied to the second gate electrode G2 and the third gate electrode G3, the tendency to increase lateral stress may decrease.

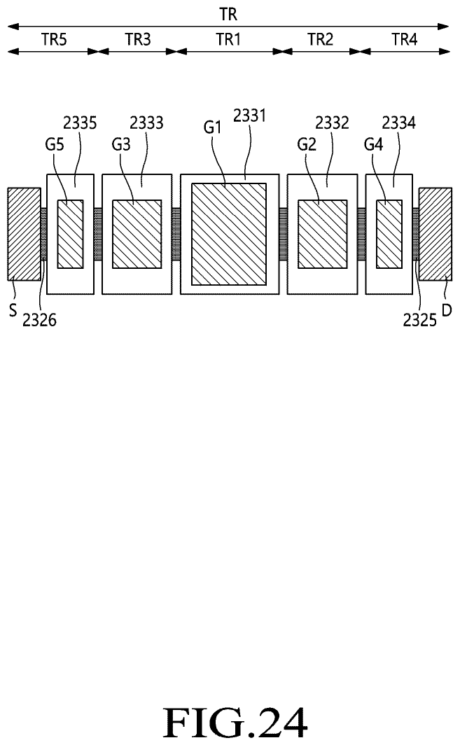

FIG. 24 is a plan view illustrating a transistor TR including first to fifth transistors TR1, TR2, TR3, TR4, and TR5 in a display device according to embodiments of the disclosure. FIG. 24 may be a plan view of a transistor TR corresponding to the cross-sectional structure of FIG. 23, and no duplicate description may be given of for substantially the same configuration as the configuration of FIG. 8.

FIG. 24 may illustrate an upper surface of a transistor TR including first to fifth transistors TR1, TR2, TR3, TR4, and TR5. The first to fifth gate insulation layers 2331, 2332, 2333, 2334 and 2335 and the first to fifth gate electrodes G1, G2, G3, G4, and G5 may be disposed between the source electrode S and the drain electrode D. A sixth conductive portion 2326 may be disposed between the source electrode S and the fifth gate insulation layer 2335, a fourth conductive portion 2324 may be disposed between the fifth gate insulation layer 2335 and the third gate insulation layer 2333, a first conductive portion 2321 may be disposed between the second gate insulation layer 2332 and the fourth gate insulation layer 2334, and a fifth conductive portion 2325 may be disposed between the fourth gate insulation layer 2334 and the drain electrode D.

In the display device according to embodiments of the disclosure, since the gate insulation layer material is etched considering the maximum value of the process margin between the second gate electrode G2 and the fourth gate electrode G4, the length of the upper surface of the first conductive portion 2321 may be minimized. For the same reason, the length of the upper surface of the fourth conductive portion 2324 may be minimized.

A display device according to an embodiment of the disclosure may be described as follows.

A display device according to embodiments of the disclosure may comprise a substrate, and a transistor disposed on the substrate.

According to the display device according to embodiments of the disclosure, the transistor may include an active layer on the substrate, a first gate insulation layer disposed on the active layer, a second gate insulation layer disposed on the active layer, and spaced apart from the first gate insulation layer in a first direction, a first gate electrode disposed on the first gate insulation layer, a second gate electrode disposed on the second gate insulation layer, and spaced apart from the first gate electrode, a drain electrode connected to a portion of the active layer, and a source electrode connected to another portion of the active layer.

According to the display device according to embodiments of the disclosure, the active layer may include a first channel portion overlapping at least a portion of the first gate electrode, a second channel portion overlapping at least a portion of the second gate electrode, a first conductive portion positioned in the first direction of the second channel portion, a second conductive portion positioned between the first channel portion and the second channel portion, and a third conductive portion positioned in a second direction opposite to the first direction of the first channel portion.

According to the display device according to embodiments of the disclosure, at least a portion of the first conductive portion may overlap the second gate electrode, and the second conductive portion may not overlap the first gate electrode and the second gate electrode.

According to the display device according to embodiments of the disclosure, the drain electrode may be connected to the first conductive portion, the source electrode may be connected to the third conductive portion, and at least a portion of the third conductive portion may overlap the first gate electrode.

According to the display device according to embodiments of the disclosure, the active layer may include an oxide semiconductor material.

The display device according to embodiments of the disclosure may further comprise an interlayer insulation layer disposed on the first gate electrode and the second gate electrode.

According to the display device according to embodiments of the disclosure, the interlayer insulation layer may be interposed in a space where the first gate electrode and the second gate electrode may be spaced apart from each other and a space where the first gate insulation layer and the second gate insulation layer may be spaced apart from each other, to contact an upper surface of the second conductive portion.

According to the display device according to embodiments of the disclosure, the interlayer insulation layer may include hydrogen, and the first conductive portion, the second conductive portion, and the third conductive portion may include hydrogen.

According to the display device according to embodiments of the disclosure, the same gate voltage may be applied to the first gate electrode and the second gate electrode.

According to the display device according to embodiments of the disclosure, a gate voltage may be applied to the first gate electrode, and a ground voltage may be applied to the second gate electrode.

According to the display device according to embodiments of the disclosure, a gate voltage may be applied to the first gate electrode, and the second gate electrode may be electrically floated.

The display device according to embodiments of the disclosure may further comprise a buffer layer between the substrate and the active layer, and a metal pattern disposed between the substrate and the buffer layer and overlapping the first channel portion and the second channel portion.

According to the display device according to embodiments of the disclosure, the metal pattern may have one of a state electrically connected to the source electrode, a state in which a gate voltage applied to the first gate electrode may be applied, a state in which a ground voltage may be applied, and an electrically floated state.

The display device according to embodiments of the disclosure may further comprise a buffer layer between the substrate and the active layer, a first metal pattern disposed between the substrate and the buffer layer, and overlapping the first channel portion, and a second metal pattern disposed between the substrate and the buffer layer, spaced apart from the first metal pattern, and overlapping the second channel portion.

According to the display device according to embodiments of the disclosure, each of the first metal pattern and the second metal pattern may have one of a state electrically connected to the source electrode, a state in which a gate voltage applied to the first gate electrode may be applied, a state in which a ground voltage may be applied, and an electrically floated state.

The display device according to embodiments of the disclosure may further comprise a gate line disposed on the substrate and supplying a gate signal to a subpixel, and a gate-in panel circuit disposed on the substrate and configured to output the gate signal to the gate line. The transistor may be included in the gate-in panel circuit.

According to the display device according to embodiments of the disclosure, the gate-in panel circuit may include a gate output buffer configured to output the gate signal and including a pull-up transistor and a pull-down transistor, a carry output buffer configured to output a carry signal and including a carry pull-up transistor and a carry pull-down transistor, and a control circuit controlling a voltage state of a Q node corresponding to a gate node of the pull-up transistor and a gate node of the carry pull-up transistor and a voltage state of a QB node corresponding to a gate node of the pull-down transistor and a gate node of the carry pull-down transistor.

According to the display device according to embodiments of the disclosure, the control circuit may include a control transistor having a drain node to which a high-potential voltage may be applied, and wherein at least one of the pull-up transistor, the carry pull-up transistor, and the control transistor corresponds to the transistor of the display device according to embodiments of the disclosure.

The display device according to embodiments of the disclosure may further comprise a third gate insulation layer disposed on the active layer, and spaced apart from the first gate insulation layer in the second direction, and a third gate electrode disposed on the third gate insulation layer, and spaced apart from the first gate electrode.

According to the display device according to embodiments of the disclosure, the active layer may include a third channel portion positioned in the second direction from the third conductive portion and overlapping at least a portion of the third gate electrode, and a fourth conductive portion positioned in the second direction from the third channel portion.

The display device according to embodiments of the disclosure may further comprise an interlayer insulation layer disposed on the first gate electrode and the third gate electrode.

According to the display device according to embodiments of the disclosure, the interlayer insulation layer may be interposed in a space where the first gate electrode and the third gate electrode may be spaced apart from each other and a space where the first gate insulation layer and the third gate insulation layer may be spaced apart from each other, to contact an upper surface of the third conductive portion.

According to the display device according to embodiments of the disclosure, at least a portion of the first conductive portion may overlap the second gate electrode, the second conductive portion may not overlap the first gate electrode and the second gate electrode, the third conductive portion may not overlap the first gate electrode and the third gate electrode, and at least a portion of the fourth conductive portion may overlap the third gate electrode.

According to the display device according to embodiments of the disclosure, the drain electrode may be connected to the first conductive portion, and the source electrode may be connected to the fourth conductive portion.

According to the display device according to embodiments of the disclosure, when a gate voltage may be applied to the first gate electrode, each of the second gate electrode and the third gate electrode may have one of a state in which the gate voltage may be applied, a state in which a ground voltage may be applied, and an electrically floated state.

The display device according to embodiments of the disclosure may further comprise a buffer layer between the substrate and the active layer, and a metal pattern between the substrate and the buffer layer.

According to the display device according to embodiments of the disclosure, the metal pattern may have one of a state electrically connected to the source electrode, a state in which a gate voltage applied to the first gate electrode may be applied, a state in which a ground voltage may be applied, and an electrically floated state.

The display device according to embodiments of the disclosure may further comprise a buffer layer between the substrate and the active layer, a first metal pattern disposed between the substrate and the buffer layer, and overlapping the first channel portion, a second metal pattern disposed between the substrate and the buffer layer, spaced apart from the first metal pattern, and overlapping the second channel portion, and a third metal pattern disposed between the substrate and the buffer layer, spaced apart from the first metal pattern, and overlapping the third channel portion.

According to the display device according to embodiments of the disclosure, each of the first metal pattern, the second metal pattern, and the third metal pattern may have one of a state electrically connected to the source electrode, a state in which a gate voltage applied to the first gate electrode may be applied, a state in which a ground voltage may be applied, and an electrically floated state.

According to the display device according to embodiments of the disclosure, a distance at which the second gate electrode is spaced apart from the first gate electrode may be larger than or equal to each of a distance at which the second gate insulation layer is spaced apart from the first gate insulation layer and a width of an upper surface of the second conductive portion.

According to the display device according to embodiments of the disclosure, the transistor is formed by connecting in series a first transistor, a second transistor and a third transistor, and the resistance of the first channel portion is increased by disposing the second transistor and the third transistor that function as a kind of resistor at two opposite ends of the first transistor.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalent.

What is claimed:

1. A display device, comprising:
a substrate; and
a transistor disposed on the substrate, wherein the transistor includes:
an active layer on the substrate;
a first gate insulation layer disposed on the active layer;
a second gate insulation layer disposed on the active layer, and spaced apart from the first gate insulation layer in a first direction;
a first gate electrode disposed on the first gate insulation layer;
a second gate electrode disposed on the second gate insulation layer, and spaced apart from the first gate electrode;
a drain electrode connected to a portion of the active layer; and
a source electrode connected to another portion of the active layer, wherein the active layer includes:
a first channel portion overlapping at least a portion of the first gate electrode;
a second channel portion overlapping at least a portion of the second gate electrode;
a first conductive portion positioned in the first direction of the second channel portion;
a second conductive portion positioned between the first channel portion and the second channel portion; and
a third conductive portion positioned in a second direction opposite to the first direction of the first channel portion.

2. The display device of claim 1, wherein at least a portion of the first conductive portion overlaps the second gate electrode, and
wherein the second conductive portion does not overlap the first gate electrode and the second gate electrode.

3. The display device of claim 1, wherein the drain electrode is connected to the first conductive portion,
wherein the source electrode is connected to the third conductive portion, and
wherein at least a portion of the third conductive portion overlaps the first gate electrode.

4. The display device of claim 1, wherein the active layer includes an oxide semiconductor material.

5. The display device of claim 1, further comprising an interlayer insulation layer disposed on the first gate electrode and the second gate electrode,
wherein the interlayer insulation layer is interposed in a space where the first gate electrode and the second gate electrode are spaced apart from each other and a space where the first gate insulation layer and the second gate insulation layer are spaced apart from each other, to contact an upper surface of the second conductive portion.

6. The display device of claim 5, wherein the interlayer insulation layer includes hydrogen, and
wherein the first conductive portion, the second conductive portion, and the third conductive portion include hydrogen.

7. The display device of claim 1, wherein a same gate voltage is applied to the first gate electrode and the second gate electrode.

8. The display device of claim 1, wherein a gate voltage is applied to the first gate electrode, and a ground voltage is applied to the second gate electrode.

9. The display device of claim 1, wherein a gate voltage is applied to the first gate electrode, and the second gate electrode is electrically floated.

10. The display device of claim 1, further comprising:
a buffer layer between the substrate and the active layer; and
a metal pattern disposed between the substrate and the buffer layer and overlapping the first channel portion and the second channel portion, wherein the metal pattern has one of:
a state electrically connected to the source electrode;
a state in which a gate voltage applied to the first gate electrode is applied;
a state in which a ground voltage is applied; and
an electrically floated state.

11. The display device of claim 1, further comprising:
a buffer layer between the substrate and the active layer;
a first metal pattern disposed between the substrate and the buffer layer, and overlapping the first channel portion; and
a second metal pattern disposed between the substrate and the buffer layer, spaced apart from the first metal pattern, and overlapping the second channel portion, wherein each of the first metal pattern and the second metal pattern has one of:
a state electrically connected to the source electrode;
a state in which a gate voltage applied to the first gate electrode is applied;
a state in which a ground voltage is applied; and
an electrically floated state.

12. The display device of claim 1, further comprising:
a gate line disposed on the substrate and supplying a gate signal to a subpixel; and
a gate-in panel circuit disposed on the substrate and configured to output the gate signal to the gate line,
wherein the transistor is included in the gate-in panel circuit.

13. The display device of claim 12, wherein the gate-in panel circuit includes:
a gate output buffer configured to output the gate signal and including a pull-up transistor and a pull-down transistor;
a carry output buffer configured to output a carry signal and including a carry pull-up transistor and a carry pull-down transistor; and
a control circuit controlling a voltage state of a Q node corresponding to a gate node of the pull-up transistor and a gate node of the carry pull-up transistor and a voltage state of a QB node corresponding to a gate node of the pull-down transistor and a gate node of the carry pull-down transistor,
wherein the control circuit includes a control transistor having a drain node to which a high-potential voltage is applied, and
wherein at least one of the pull-up transistor, the carry pull-up transistor, and the control transistor corresponds to the transistor included in the gate-in panel circuit.

14. The display device of claim 1, further comprising:
a third gate insulation layer disposed on the active layer, and spaced apart from the first gate insulation layer in the second direction; and
a third gate electrode disposed on the third gate insulation layer, and spaced apart from the first gate electrode, wherein the active layer includes:
a third channel portion positioned in the second direction from the third conductive portion and overlapping at least a portion of the third gate electrode; and
a fourth conductive portion positioned in the second direction from the third channel portion.

15. The display device of claim 14, further comprising an interlayer insulation layer disposed on the first gate electrode and the third gate electrode,
wherein the interlayer insulation layer is interposed in a space where the first gate electrode and the third gate electrode are spaced apart from each other and a space where the first gate insulation layer and the third gate insulation layer are spaced apart from each other, to contact an upper surface of the third conductive portion.

16. The display device of claim 14, wherein at least a portion of the first conductive portion overlaps the second gate electrode,
wherein the second conductive portion does not overlap the first gate electrode and the second gate electrode,
wherein the third conductive portion does not overlap the first gate electrode and the third gate electrode,
wherein at least a portion of the fourth conductive portion overlaps the third gate electrode,
wherein the drain electrode is connected to the first conductive portion, and
wherein the source electrode is connected to the fourth conductive portion.

17. The display device of claim 14, wherein when a gate voltage is applied to the first gate electrode, each of the second gate electrode and the third gate electrode has one of:
a state in which the gate voltage is applied;
a state in which a ground voltage is applied; and
an electrically floated state.

18. The display device of claim 14, further comprising:
a buffer layer between the substrate and the active layer; and
a metal pattern between the substrate and the buffer layer, wherein the metal pattern has one of:
a state electrically connected to the source electrode;
a state in which a gate voltage applied to the first gate electrode is applied;
a state in which a ground voltage is applied; and
an electrically floated state.

19. The display device of claim 14, further comprising:
a buffer layer between the substrate and the active layer;
a first metal pattern disposed between the substrate and the buffer layer, and overlapping the first channel portion;
a second metal pattern disposed between the substrate and the buffer layer, spaced apart from the first metal pattern, and overlapping the second channel portion; and
a third metal pattern disposed between the substrate and the buffer layer, spaced apart from the first metal pattern, and overlapping the third channel portion, wherein each of the first metal pattern, the second metal pattern, and the third metal pattern has one of:
a state electrically connected to the source electrode;
a state in which a gate voltage applied to the first gate electrode is applied;
a state in which a ground voltage is applied; and
an electrically floated state.

20. The display device of claim 1, wherein a distance at which the second gate electrode is spaced apart from the first gate electrode is larger than or equal to each of a distance at which the second gate insulation layer is spaced apart from the first gate insulation layer and a length of an upper surface of the second conductive portion.
